(19) United States
(12) Patent Application Publication
(10) Pub. No.: US 2024/0405009 A1
(43) Pub. Date: Dec. 5, 2024

(54) DEVICES, SYSTEMS AND METHODS RELATED TO DUAL-SIDED MODULES

(71) Applicant: SKYWORKS SOLUTIONS, INC., Irvine, CA (US)

(72) Inventors: Sundeep Nand NANGALIA, Raleigh, NC (US); Howard E. CHEN, Anaheim, CA (US); Anthony James LOBIANCO, Irvine, CA (US)

(21) Appl. No.: 18/674,819

(22) Filed: May 25, 2024

Related U.S. Application Data
(60) Provisional application No. 63/470,423, filed on Jun. 1, 2023.

(51) Int. Cl. H01L 25/18; H01L 23/00; H01L 23/31; H01L 23/498; H01L 23/538; H01L 23/552

(52) U.S. Cl. CPC H01L 25/18; H01L 23/3107; H01L 23/49811; H01L 23/5383; H01L 24/97; H01L 23/552; H01L 24/08; H01L 2224/08225; H01L 2224/97

(57) ABSTRACT

A dual-sided module can include a redistribution layer having first and second sides, and a first-side portion implemented on the first side of the redistribution layer and including a first component mounted on the first side of the redistribution layer, and a first mold structure implemented to at least partially encapsulate the first component. The dual-sided module can further include a second-side portion implemented on the second side of the redistribution layer and including a second component mounted on the second side of the redistribution layer, a plurality of conductive mounting structures, and a second mold structure implemented to at least partially encapsulate the second component. The second mold structure can further encapsulate the conductive mounting features while providing respective exposed mounting surfaces of the conductive mounting features.

### CROSS-REFERENCE TO RELATED APPLICATION(S)

This application claims priority to U.S. Provisional Application No. 63/470,423 filed Jun. 1, 2023, entitled DEVICES, SYSTEMS AND METHODS RELATED TO DUAL-SIDED MODULES, the disclosure of which is hereby expressly incorporated by reference herein in its entirety.

### BACKGROUND

### Field

The present disclosure relates to packaged electronic modules such as packaged modules for radio-frequency applications.

### Description of the Related Art

In many electronics applications, radio-frequency (RF) circuits and/or circuit elements are implemented as parts of packaged modules. A packaged module typically includes a substrate configured to receive and support a plurality of components such as semiconductor die and/or circuit elements such as discrete passive components. In some applications, such a packaged module can include one or more of the foregoing devices mounted on each of both sides of the substrate.

### SUMMARY

In accordance with a number of implementations, the present disclosure relates to a packaged module that includes a redistribution layer having first and second sides, and a first-side portion implemented on the first side of the redistribution layer and including a first component mounted on the first side of the redistribution layer. The first-side portion further includes a first mold structure implemented to at least partially encapsulate the first component. The packaged module further includes a second-side portion implemented on the second side of the redistribution layer and including a second component mounted on the second side of the redistribution layer, and a plurality of conductive mounting structures. The second-side portion further includes a second mold structure implemented to at least partially encapsulate the second component. The second mold structure further encapsulates the conductive mounting features while providing respective exposed mounting surfaces of the conductive mounting features.

In some embodiments, the redistribution layer can be implemented as a multi-layer redistribution layer having a first outermost layer that defines the first side and a second outermost layer that defines the second side. In some embodiments, the first component can be mounted directly on the first side, and the second component can be mounted directly on the second side.

In some embodiments, first component can be implemented as a die, and the second component can be implemented as a die. Each of the first and second die can be configured to provide a radio-frequency functionality. The radio-frequency functionality of each of the first and second die can include a filtering functionality. Each of the first and second die can be configured as an acoustic filter device. The first acoustic filter device can be a multilayer piezoelectric substrate (MPS) filter or a bulk acoustic wave (BAW) filter, and the second acoustic filter device can be an MPS filter or a BAW filter.

In some embodiments, the conductive mounting structures of the second-side portion can be implemented as ball-shaped structures or as metal posts.

In some embodiments, first mold structure can be implemented fully encapsulate non-mounting surface and side walls of the first component. In some embodiments, the first mold structure can be implemented to expose a non-mounting surface of the first component. The exposed non-mounting surface of the first component can result from a thinning operation that removes a portion of the first component. The exposed non-mounting surface of the first component can include a ground surface that provides a desired thickness of the first-side portion.

In some embodiments, the second mold structure can be implemented fully encapsulate non-mounting surface and side walls of the second component.

In some embodiments, the second mold structure can be implemented to expose a non-mounting surface of the second component. The exposed non-mounting surface of the second component can result from a thinning operation that removes a portion of the second component. The exposed non-mounting surface of the second component can include a ground surface that provides a desired thickness of the second-side portion.

In some embodiments, the packaged module can further include an electromagnetic shielding feature including a conductive shielding layer that substantially covers all sides of the packaged module except a mounting side associated with the exposed mounting surfaces of the conductive mounting features. The conductive shielding layer can be electrically connected to a ground plane within the redistribution layer. The conductive shielding layer can include a conductive layer formed from a conformal deposition process.

In some embodiments, the first component can be mounted on the first side of the redistribution layer to provide a no-gap configuration therebetween. The first component can include a mounting side that is patterned to allow the mounting side to be mated directly with a corresponding patterned area on the first side of the redistribution layer.

In some embodiments, the second component can be mounted on the second side of the redistribution layer to provide a gap therebetween. The second component can be mounted to the second side of the redistribution layer with a surface mount technology configuration. The second mold structure can also fill the gap between the second component and the second side of the redistribution layer.

In some embodiments, the redistribution layer can include a passive circuit element implemented as one or more features printed on one or more layers of the redistribution layer. In some embodiments, the passive circuit element can include an inductor, a capacitor or a resistor.

In some implementations, the present disclosure relates to a method for manufacturing a packaged module. The method includes providing a carrier, forming a first-side portion of a dual-sided module on the carrier, and removing the carrier from the first-side portion to provide a surface. The method further includes providing or forming a redistribution layer on the first-side portion, such that a first side of the redistribution layer engages the surface of the first-side portion and a second side of the redistribution layer is opposite from the first side. The method further includes forming a second-side portion of the dual-sided module on the second side of the redistribution layer.

In some embodiments, the forming of the first-side portion can include attaching a first component on a surface of the carrier, and forming a first mold structure over the surface of the carrier to at least partially encapsulate the first component.

In some embodiments, the removing of the carrier from the first-side portion can include a debonding process.

In some embodiments, the redistribution layer can include a pre-fabricated redistribution layer having multiple layers such that a first outermost layer defines the first side and a second outermost layer defines the second side.

In some embodiments, the first side of the redistribution layer can directly engage the surface of the first-side portion. In some embodiments, the first side of the redistribution layer can engage a mounting surface of the first component to provide a gapless interconnect between the first component and the first side of the redistribution layer.

In some embodiments, the redistribution layer can be formed over the surface of the first-side portion. The forming of the redistribution layer can include forming multiple layers such that a first outermost layer defines the first side and a second outermost layer defines the second side.

In some embodiments, the first side of the redistribution layer can directly engage the surface of the first-side portion. In some embodiments, the first side of the redistribution layer can engage a mounting surface of the first component to provide a gapless interconnect between the first component and the first side of the redistribution layer.

In some embodiments, the forming of the second-side portion can include mounting a second component on the second side of the redistribution layer, implementing a plurality of conductive mounting features on the second side of the redistribution layer, and forming a second mold structure to at least partially encapsulate the second component and the conductive mounting features while providing respective exposed mounting surfaces of the conductive mounting features.

In some embodiments, the mounting of the second component can be performed before the implementing of the plurality of conductive mounting features. In some embodiments, the mounting of the second component can be performed after the implementing of the plurality of conductive mounting features.

In some embodiments, the forming of the second mold structure can include forming a mold structure the fully covers the second component and the conductive mounting features, and performing a thinning operation to expose the mounting surfaces of the conductive mounting features.

In some embodiments, the thinning operation can be performed to expose non-mounting surface of the second component. The thinning operation can remove a portion of the second component. The thinning operation can include a grinding operation that provides a ground surface as the exposed non-mounting surface of the second component, to thereby provide a desired thickness of the second-side portion.

In some embodiments, the forming of the first mold structure can include forming a mold structure the fully covers the first component, and performing a thinning operation to reduce the thickness of the first mold structure. The thinning operation can be performed to expose non-mounting surface of the first component. The thinning operation can remove a portion of the first component. The thinning operation can include a grinding operation that provides a ground surface as the exposed non-mounting surface of the first component, to thereby provide a desired thickness of the first-side portion.

In some embodiments, the carrier can include a metal carrier.

In some embodiments, the carrier can be dimensioned to allow processing of an array of units with each including a respective first-side portion, a respective redistribution layer, and a respective second-side portion, such that an array of packaged modules are manufactured while in an array format. In some embodiments, the method can further include singulating the array of packaged modules into a plurality of individual packaged modules.

In some implementations, the present disclosure relates to a method for manufacturing packaged modules. The method includes providing a carrier, and providing or forming a redistribution layer on the carrier, such that the redistribution layer includes first and second sides with the second side engaging the carrier. The method further includes forming a first-side portion of a dual-sided module on the first side of the redistribution layer, removing the carrier from the second side of the redistribution layer, and forming a second-side portion of the dual-sided module on the second side of the redistribution layer.

In some embodiments, the forming of the first-side portion can include attaching a first component on the first side of the redistribution layer, and forming a first mold structure over the first side of the redistribution layer to at least partially encapsulate the first component.

In some embodiments, the removing of the carrier from the redistribution layer can include a debonding process.

In some embodiments, the redistribution layer can be a pre-fabricated redistribution layer having multiple layers such that a first outermost layer defines the first side and a second outermost layer defines the second side. In some embodiments, the first side of the redistribution layer can engage a mounting surface of the first component to provide a gapless interconnect between the first component and the first side of the redistribution layer. In some embodiments, the second side of the redistribution layer can directly engage the carrier.

In some embodiments, the redistribution layer can be formed over the carrier. The forming of the redistribution layer can include forming multiple layers such that a first outermost layer defines the first side and a second outermost layer defines the second side. In some embodiments, the first side of the redistribution layer can engage a mounting surface of the first component to provide a gapless interconnect between the first component and the first side of the redistribution layer. In some embodiments, the second side of the redistribution layer can directly engage the carrier.

In some embodiments, the forming of the second-side portion can include mounting a second component on the second side of the redistribution layer, implementing a plurality of conductive mounting features on the second side of the redistribution layer, and forming a second mold structure to at least partially encapsulate the second component and the conductive mounting features while providing respective exposed mounting surfaces of the conductive mounting features. In some embodiments, the mounting of the second component can be performed before the implementing of the plurality of conductive mounting features. In some embodiments, the mounting of the second component can be performed after the implementing of the plurality of conductive mounting features.

In some embodiments, the forming of the second mold structure can include forming a mold structure that fully covers the second component and the conductive mounting features, and performing a thinning operation to expose the mounting surfaces of the conductive mounting features. The thinning operation can be performed to expose non-mounting surface of the second component. The thinning operation can remove a portion of the second component. The thinning operation can include a grinding operation that provides a ground surface as the exposed non-mounting surface of the second component, to thereby provide a desired thickness of the second-side portion.

In some embodiments, the forming of the first mold structure can include forming a mold structure the fully covers the first component, and performing a thinning operation to reduce the thickness of the first mold structure. The thinning operation can be performed to expose a non-mounting surface of the first component. The thinning operation can remove a portion of the first component. The thinning operation can include a grinding operation that provides a ground surface as the exposed non-mounting surface of the first component, to thereby provide a desired thickness of the first-side portion.

In some embodiments, the carrier can include a metal carrier. In some embodiments, the carrier can be dimensioned to allow processing of an array of units each including a respective first-side portion, a respective redistribution layer, and a respective second-side portion, such that an array of packaged modules are manufactured while in an array format. In some embodiments, the method can further include singulating the array of packaged modules into a plurality of individual packaged modules.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIGS. 1A to 1E show examples of dual-sided modules where each includes a substrate with a first side and a second side.

FIGS. 2A to 2J show various stages of a process that can be utilized to fabricate a dual-sided module such as any one of the modules of FIGS. 1A to 1E.

FIG. 3 shows a dual-sided module that includes a configuration where a first mold structure is dimensioned to expose at least a portion of the non-mounting side of a component on the first side of a substrate.

FIGS. 4A to 4C show an example process that can be utilized to fabricate the dual-sided module of FIG. 3.

FIGS. 5A to 5C show example stages of fabrication where multiple units are processed while in an array format and then singulated to provide multiple dual-sided units.

FIGS. 6A to 6C show that in some embodiments, a rectangular shaped carrier can be utilized to fabricate an array of dual-sided modules having one or more features as described herein.

FIG. 7A show a dual-sided module that is similar to the module 100 of FIG. 2J, where a redistribution layer (RDL) is shown to have examples of metal layers/traces, vias and pads for providing redistribution of electrical connections.

FIG. 7B shows an enlarged view of the RDL of FIG. 7A by itself.

FIGS. 8A to 8E show various stages of such a process that can be implemented to fabricate a dual-sided module, where an RDL is provided or constructed on a carrier before building of a side portion of the module.

FIG. 9 shows that in some embodiments, a dual-sided module having one or more features as described herein can include a first component implemented as a first radio-frequency (RF) device, and a second component implemented as a second RF device.

FIG. 10 shows that in some embodiments, the first RF device of FIG. 9 can be a first filter device, and the second RF device of FIG. 9 can be a second filter device.

FIGS. 11A to 11D show non-limiting examples where first and second components of a dual-sided module can be implemented as different combinations of multilayer piezoelectric substrate (MPS) and bulk acoustic wave (BAW) filters.

FIG. 12 shows that in some embodiments, one or more features of the present disclosure can be implemented in a module packaging system.

FIG. 13 shows a dual-sided module having one or more features as described herein, where a first component is coupled to a first side of an RDL-substrate, and a second component is coupled to a second side of the RDL-substrate.

FIG. 14 shows that in some embodiments, a first interconnect can be configured such that a first component of a dual-sided module is mounted to a first side of an RDL-substrate utilizing a surface mount technology (SMT) process.

FIG. 15 shows that in some embodiments, a first interconnect of a dual-sided module can be similar to the example of FIG. 13, and a second interconnect of the dual-sided module can also be implemented to provide a no-gap interconnect configuration.

FIG. 16 shows a dual-sided module fabricated as described herein, and further include a conformal shielding layer that covers the non-mounting side and side walls.

FIG. 17 shows that in some embodiments, a dual-sided module having one or more features as described herein can include a passive circuit element implemented as a part of an RDL.

FIG. 18A shows that in some embodiments, a dual-sided module having one or more features as described herein can include an inductor implemented as a part of an RDL.

FIG. 18B shows that in some embodiments, a dual-sided module having one or more features as described herein can include a capacitor implemented as a part of an RDL.

FIG. 18C shows that in some embodiments, a dual-sided module having one or more features as described herein can include a resistor implemented as a part of an RDL.

### DETAILED DESCRIPTION OF SOME EMBODIMENTS

The headings provided herein, if any, are for convenience only and do not necessarily affect the scope or meaning of the claimed invention.

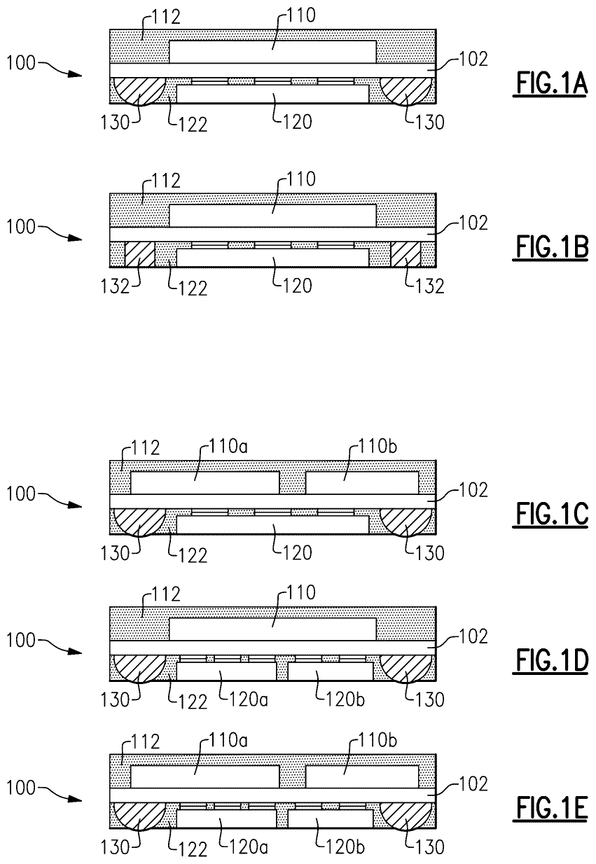

Described herein are various examples related to dual-sided modules that can be implemented for electronic applications such as radio-frequency (RF) applications. FIGS. 1A to 1E show examples of dual-sided (DS) modules 100 where each includes a substrate 102 with a first side (e.g., an upper side when oriented as shown) and a second side (e.g., an underside).

On the first side of the substrate 102, one or more components 110 is/are shown to be mounted. Such component(s) can be, for example, one or more die, one or more non-die components, or some combination thereof for contributing to RF functionality of the module 100. In FIGS. 1A, 1B and 1D, each module 100 is shown to have one component 110. In FIGS. 1C and 1E, each module 100 is shown to have two components 110a, 110b. Examples of such component(s) (110) are provided herein in greater detail.

On the second side of the substrate 102, one or more components 120 is/are shown to be mounted. Such component(s) can be, for example, one or more die, one or more non-die components, or some combination thereof for contributing to RF functionality of the module 100. In FIGS. 1A, 1B and 1C, each module 100 is shown to have one component 120. In FIGS. 1D and 1E, each module 100 is shown to have two components 120a, 120b. Examples of such component(s) (120) are provided herein in greater detail.

Based on the foregoing examples of FIGS. 1A to 1E, it will be understood that a dual-sided module having one or more features as described herein can include one or more components on one side, and one or more components on the other side of a substrate (102).

Referring to FIGS. 1A to 1E, each module 100 is shown to have a first mold structure 112 formed on the first side of the substrate 102, and a second mold structure 122 formed on the second side of the substrate 102. Each of the first and second mold structures 112, 122 can be dimensioned to have a desired thickness, such that the overall thickness of the module 100 is determined by the thicknesses of the first and second mold structures 112, 122 and the thickness of the substrate 102.

In the examples of FIGS. 1A to 1E, the first mold structure 112 is shown to be dimensioned to fully encapsulate non-mounting side and lateral sides of the component(s) 110. However, it will be understood that the first mold structure 112 can be dimensioned to expose at least a portion of the component(s) 110.

Similarly, the second mold structure 122 is shown to be dimensioned to expose non-mounting side of the component(s) 120. However, it will be understood that the second mold structure 122 can be dimensioned to fully encapsulate non-mounting side and lateral sides of the component(s) 120.

In the examples of FIGS. 1A and 1C to 1E, each module 100 is shown to include ball-shaped structures 130 (e.g., solder balls) configured to provide mounting and electrical connectivity functionalities for the module 100. Such ball-shaped structures 130 are shown to be mostly encapsulated by the second mold structure 122, but with respective mounting surfaces exposed to allow the foregoing mounting and electrical connectivity functionalities. Various examples hereinafter are described in the context of modules having such ball-shaped structures.

However, and as shown in the example of FIG. 1B, a module 100 having one or more features as described herein can utilize other structures such as metal post structures 132 (e.g., copper posts) configured to provide mounting and electrical connectivity functionalities for the module 100. Such metal post structures 132 are shown to be mostly encapsulated by the second mold structure 122, but with respective mounting surfaces exposed to allow the foregoing mounting and electrical connectivity functionalities.

In some embodiments, the substrate 102 in the examples of FIGS. 1A to 1E can be or include a redistribution layer (RDL). In some embodiments, such an RDL can be configured as a multilayer RDL. Examples related to methods for fabricating dual-sided modules with such RDLs are described herein in greater detail.

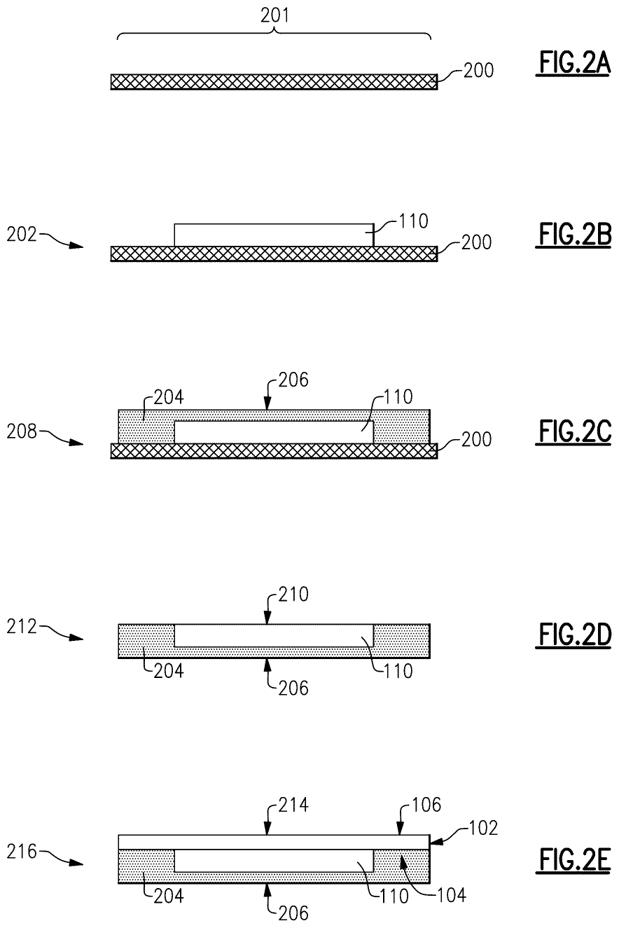

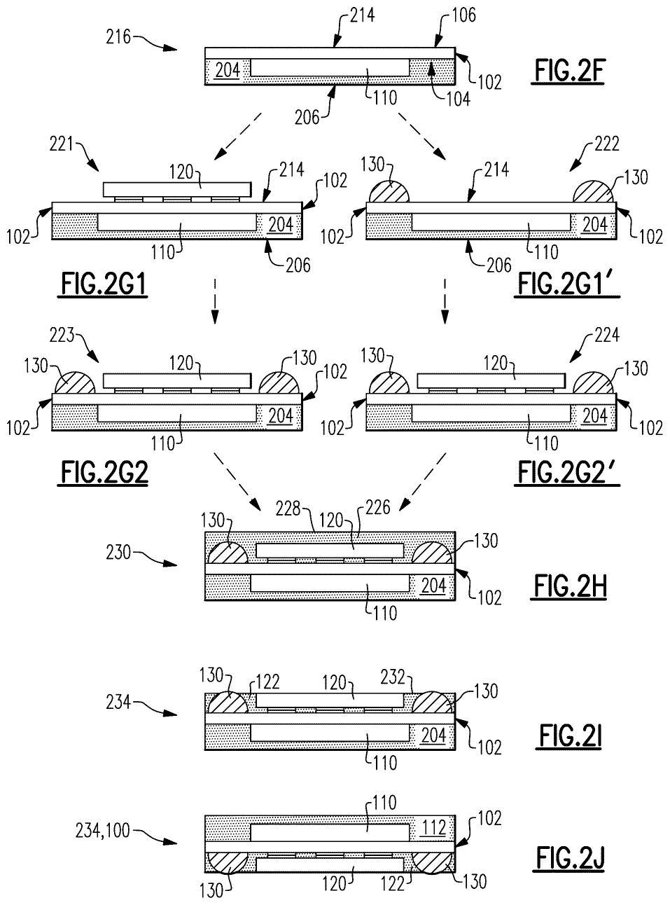

FIGS. 2A to 2J show various stages of a process that can be utilized to fabricate a dual-sided module such as any one of the modules 100 of FIGS. 1A to 1E. In the example process of FIGS. 2A to 2J, ball-shaped structures (e.g., solder balls) are utilized to provide mounting and electrical connectivity functionalities for the resulting module; however, and as discussed above other structures, such as metal posts structures 132 of FIG. 1B, can also be utilized.

FIG. 2A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 2B shows a stage where a component 110 is shown to be mounted on one side of the metal carrier 200 so as to form an assembly 202. In some embodiments, such a component (110) can be any one of components on the non-mounting side of dual-sided modules as described herein.

FIG. 2C shows a stage where a mold structure 204 is formed to partially or fully encapsulate the component 110 and define a surface 206, so as to form an assembly 208. In some embodiments, the mold structure 204 may or may not remain the same until the end of the fabrication process. If the former, the surface 206 may end up being the upper surface (when viewed as in FIGS. 1A to 1E) of the mold structure 112 on the non-mounting side of the respective module 100. If the latter, the mold structure 204 may be thinned such that the original surface 206 is removed to form a new surface.

FIG. 2D shows a stage where the metal carrier 200 in the assembly 208 of FIG. 2C is removed to provide a surface 210, so as to form an assembly 212. In some embodiments, such a removal of the metal carrier 200 can be achieved by a debonding process.

FIG. 2E shows a stage where a redistribution layer (RDL) 102 is formed or provided on the surface (210 in FIG. 2D, resulting from the removal of the metal carrier 200) of the assembly 212, so as to form an assembly 216. In some embodiments, the RDL 102 can include multiple layers, and such an RDL can be provided on the assembly 212 in a fully pre-fabricated RDL form, be built on the assembly 212 based on a partially pre-fabricated RDL form, or be built layer-by-layer on the assembly 212.

For example, suppose that an RDL includes a multi-layer assembly of a first polyimide layer, a first redistribution layer, a second polyimide layer, a second redistribution layer, a third polyimide layer and an array of under-bump metallization (UBM). In the context of such an example RDL, a fully pre-fabricated form having all of the foregoing parts can be provided on the assembly 212, a partially pre-fabricated form (e.g., a pre-fabricated assembly of first polyimide layer, first redistribution layer, second polyimide layer, second redistribution layer, and third polyimide layer) can be provided on the assembly 212 followed by formation of UBM array, or each of the foregoing parts can be built on the assembly 212 to form the assembly 216 of FIG. 2E.

In the example of FIG. 2E, it is noted that the RDL 102 includes a first side 104 and a second side 106. The first side 104 is attached to the assembly 212 (FIG. 2D), and such an assembly (212) can form one side of a dual-sided module. The second side 106 of the RDL 102 is shown to be exposed, such that the assembly 216 of FIG. 2E provides a platform with a surface 214 for formation of the other side of the dual-sided module.

FIG. 2F shows the same assembly 216 as in FIG. 2E. FIGS. 2G1 and 2G2 show an example of how a component 120 and ball-shaped structures 130 can be implemented on the surface 214 of the assembly 216 of FIG. 2F, and FIGS. 2G1′ and 2G2′ show another example of how a component 120 and ball-shaped structures 130 can be implemented on the surface 214 of the assembly 216 of FIG. 2F

In the first example, FIG. 2G1 shows a stage where a component 120 is mounted on the surface 214 of the assembly 216 of FIG. 2F, so as to form an assembly 221. In some embodiments, such a mounting process can include formation of mounting pads on the surface of the RDL 102.

Continuing with the first example, FIG. 2G2 shows a stage where ball-shaped structures 130 are implemented on the surface 214 of the assembly 221 of FIG. 2G1, so as to form an assembly 223.

In the second example, FIG. 2G1′ shows a stage where ball-shaped structures 130 are implemented on the surface 214 of the assembly 216 of FIG. 2F, so as to form an assembly 222.

Continuing with the second example, FIG. 2G2′ shows a stage where a component 120 is mounted on the surface 214 of the assembly 222 of FIG. 2G1′, so as to form an assembly 224. In some embodiments, such a mounting process can include formation of mounting pads on the surface of the RDL 102.

FIG. 2H shows a stage where a mold structure 226 is formed to encapsulate the component 120 and the ball-shaped structures 130 of the assembly 223 or 224, so as to form an assembly 230. In such an assembly (230), the mold structure 226 defines a surface 228.

FIG. 2I shows a stage where the mold structure 226 is thinned to remove the original surface 228 and provide a new surface 232, so as to form an assembly 234. In some embodiments, such a thinning process can include a grinding operation. In some embodiments, the new surface 232 resulting from the thinning operation can expose the non-mounting side of the component 120 (mounting side of the assembly 234) as well as mounting portions of the ball-shaped structures 130.

FIG. 2J shows the same assembly 234 as in FIG. 2I, except that in FIG. 2J, the assembly is oriented similar to the example modules of FIGS. 1A to 1E, with an assumption that the assembly 234 will be mounted as shown on another mounting surface. The assembly 234 of FIG. 2J is substantially the same as the example of FIG. 1A; thus, it is also indicated as a dual-sided module 100.

In the examples of FIGS. 1A to 1E and 2A to 2J, dual-sided modules 100 are depicted as having a component 110 on the first side of a respective substrate 102, and a first mold structure 112 being dimensioned to cover the non-mounting side of the component 110.

It is noted that in some embodiments, a dual-sided module having one or more features as described herein can include a component on the first side of a substrate and a first mold structure, such that the non-mounting side of the component is at least partially exposed.

For example, in some embodiments, the first mold structure can be thinned to partially or fully expose the original non-mounting side of a component (e.g., a die) on the first side of a substrate. In such a configuration, overall thickness on the first side of the substrate can be approximately the height of the original mounted component.

In another example, in some embodiments, the first mold structure can be thinned, and such a thinning operation (e.g., a grinding operation) can also remove material on the non-mounting side of a component (e.g., a die) on the first side of a substrate. Accordingly, the thinned first mold structure can expose the thinned surface (e.g., ground surface) of the component. In such a configuration, overall thickness on the first side of the substrate can be selected to be less than the height of the original mounted component, since a portion of the component may be removed.

It will be understood that in some embodiments, and as described herein, a dual-sided module having one or more features as described herein can include a component on the second side of a substrate and a second mold structure, such that the non-mounting side of the component is at least partially exposed similar to the foregoing configurations of component and first mold structure on the first side of a substrate.

FIG. 3 shows a dual-sided module 100 that includes the foregoing configuration where a first mold structure is dimensioned to expose at least a portion of the non-mounting side of a component on the first side of a substrate. More particularly, the dual-sided module 100 of FIG. 3 is shown to include a substrate 102 that includes a redistribution layer (RDL) as described herein. The substrate 102 is shown to have a first side and a second side, such that one or more components 110 is/are mounted on the first side of the substrate 102, and one or more components 120 is/are mounted on the second side of the substrate 102.

Referring to FIG. 3, the module 100 is shown to have a first mold structure 112 formed on the first side of the substrate 102, and a second mold structure 122 formed on the second side of the substrate 102. The first mold structure 112 is shown to have a selected thickness to expose at least a portion of the non-mounting side of the component 110 mounted on the first side of the substrate 102. In some embodiments, an exposed surface 111 on the non-mounting side of the component 110 can result from a portion of the component 110 being removed (e.g., by grinding) during a thinning process (e.g., grinding process) that thins the first mold structure 112.

Similarly, the second mold structure 122 is shown to have a selected thickness to expose at least a portion of the non-mounting side of the component 120 mounted on the second side of the substrate 102. In some embodiments, an exposed surface 121 on the non-mounting side of the component 120 can result from a portion of the component 120 being removed (e.g., by grinding) during a thinning process (e.g., grinding process) that thins the second mold structure 122.

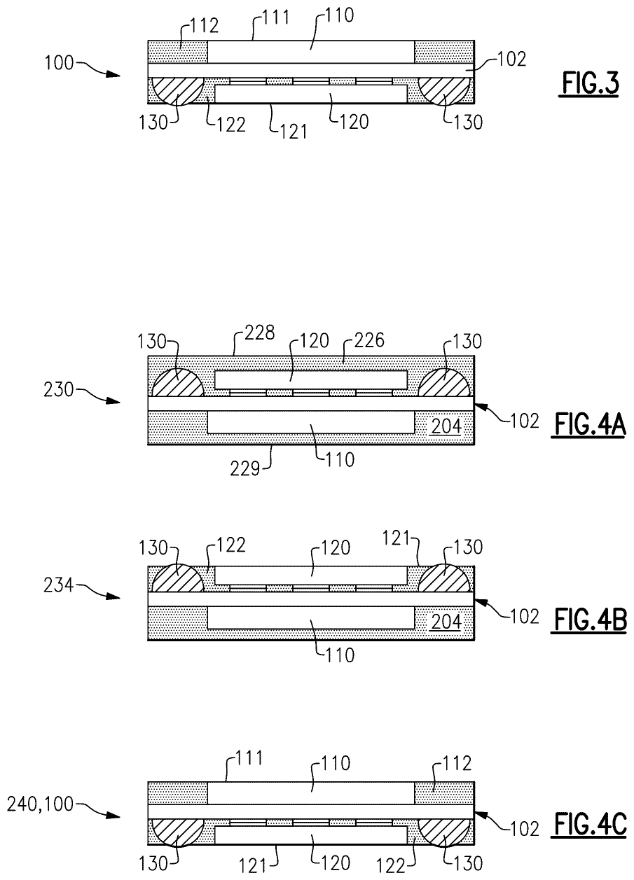

FIGS. 4A to 4C show an example process that can be utilized to fabricate the dual-sided module 100 of FIG. 3. In FIG. 4A, an assembly 230, such as the assembly 230 of FIG. 2H, can be formed or provided.

FIG. 4B shows a stage where a mold structure 226 is thinned to remove the original surface 228 (FIG. 4A) and provide a new surface 121, so as to form an assembly 234, similar to the example of FIG. 2I (with the mold structure indicated as 122). In some embodiments, such a thinning process can include a grinding operation. In some embodiments, the new surface 121 resulting from the thinning operation can expose the non-mounting side of the component 120 (mounting side of the assembly 234) as well as mounting portions of the ball-shaped structures 130.

FIG. 4C shows a stage where a mold structure 204 is thinned to remove the original surface 229 (FIG. 4A) and provide a new surface 111, so as to form an assembly 240. In some embodiments, such a thinning process can include a grinding operation. In some embodiments, the new surface 111 resulting from the thinning operation can expose the non-mounting side of the component 110 (non-mounting side of the assembly 240). In FIG. 4C, the assembly 240 is similar to the example of FIG. 3; thus, it is also indicated as a dual-sided module 100 and the corresponding first mold structure is indicated as 112.

FIGS. 2A to 2J and 4A to 4C show various stages of one module during its fabrication process. It will be understood that in some embodiments, some or all of such a fabrication can be performed for multiple units in an array format.

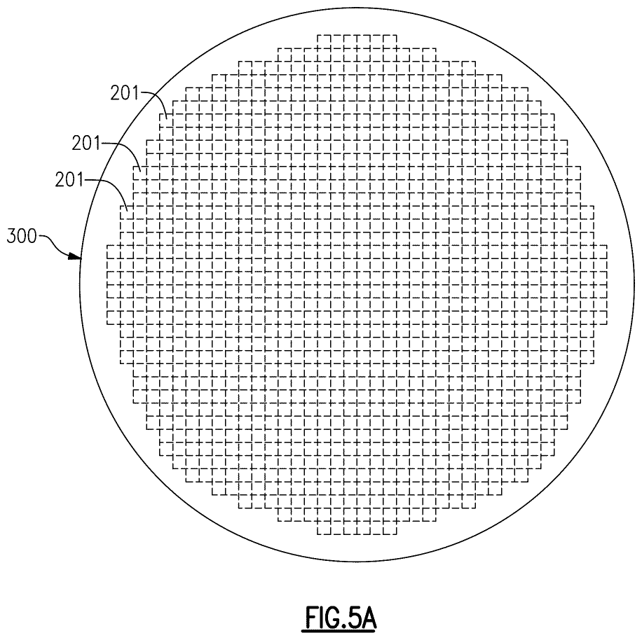

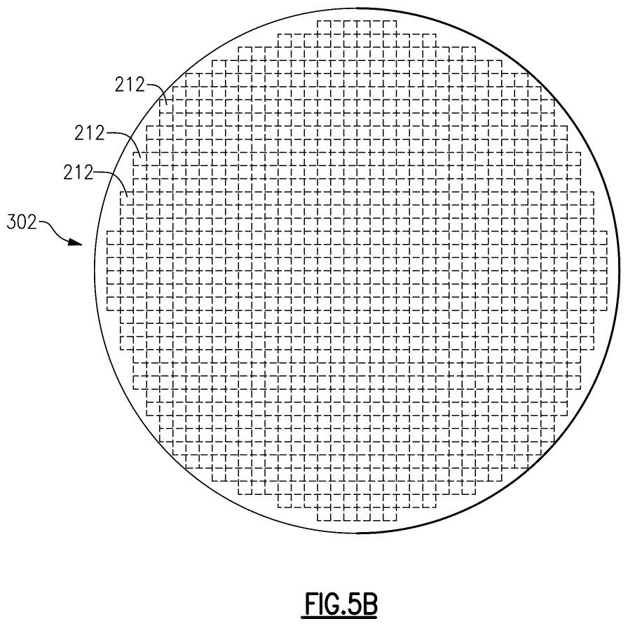

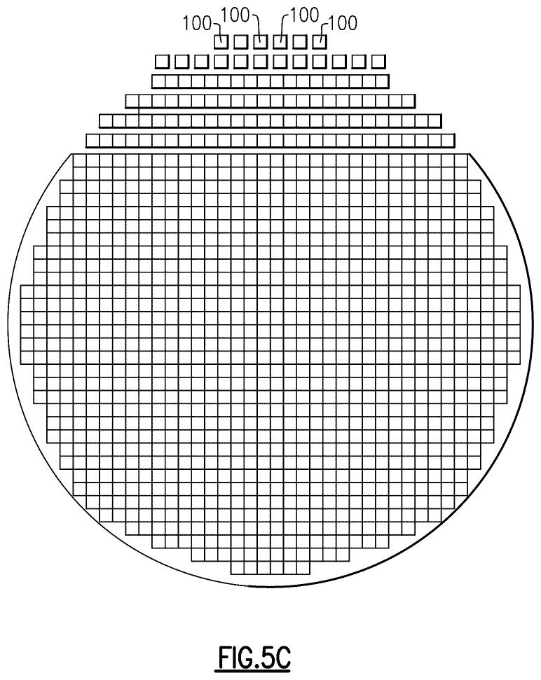

For example, FIGS. 5A to 5C show example stages of fabrication where multiple units are processed while in an array format and then singulated to provide multiple dual-sided units 100. More particularly, FIG. 5A shows a stage where a carrier 300 such as a wafer-shaped metal carrier is provided. Such a carrier can include an array of unit spaces 201, where each unit can be similar to the unit 201 described herein in reference to FIG. 2A.

FIG. 5B shows a stage where a component (110 in FIG. 2B) has been placed on each unit 201, a mold layer has been formed to cover the array of units, and the carrier 300 has been removed, so as to form an assembly 302 of units 212 (similar to the units 212 of FIG. 2D). Such process steps can correspond to each unit being similar to the steps of FIGS. 2B to 2D.

FIG. 5C shows a stage where remaining process steps have been performed similar to the steps of FIGS. 2E to 2J and/or 4A to 4C, and the resulting array of formed modules are being singulated to provide multiple dual-sided modules 100.

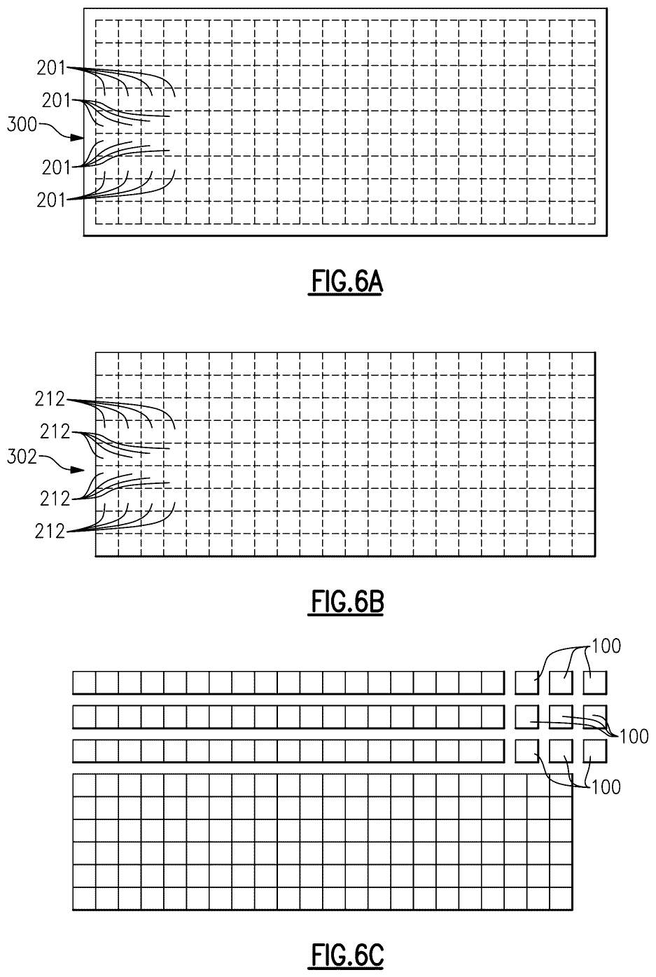

In the examples of FIGS. 5A to 5C, the carrier 300 is depicted as having a circular shape such as a wafer shape. However, it will be understood that such a carrier can have other shapes. For example, FIGS. 6A to 6C show that in some embodiments, a rectangular shaped carrier can be utilized to fabricate an array of dual-sided modules having one or more features as described herein.

More particularly, FIG. 6A shows a stage where a carrier 300 such as a rectangular-shaped metal carrier is provided. Such a carrier can include an array of unit spaces 201, where each unit can be similar to the unit 201 described herein in reference to FIG. 2A.

FIG. 6B shows a stage where a component (110 in FIG. 2B) has been placed on each unit 201, a mold layer has been formed to cover the array of units, and the carrier 300 has been removed, so as to form an assembly 302 of units 212 (similar to the units 212 of FIG. 2D). Such process steps can correspond to each unit being similar to the steps of FIGS. 2B to 2D.

FIG. 6C shows a stage where remaining process steps have been performed similar to the steps of FIGS. 2E to 2J and/or 4A to 4C, and the resulting array of formed modules are being singulated to provide multiple dual-sided modules 100.

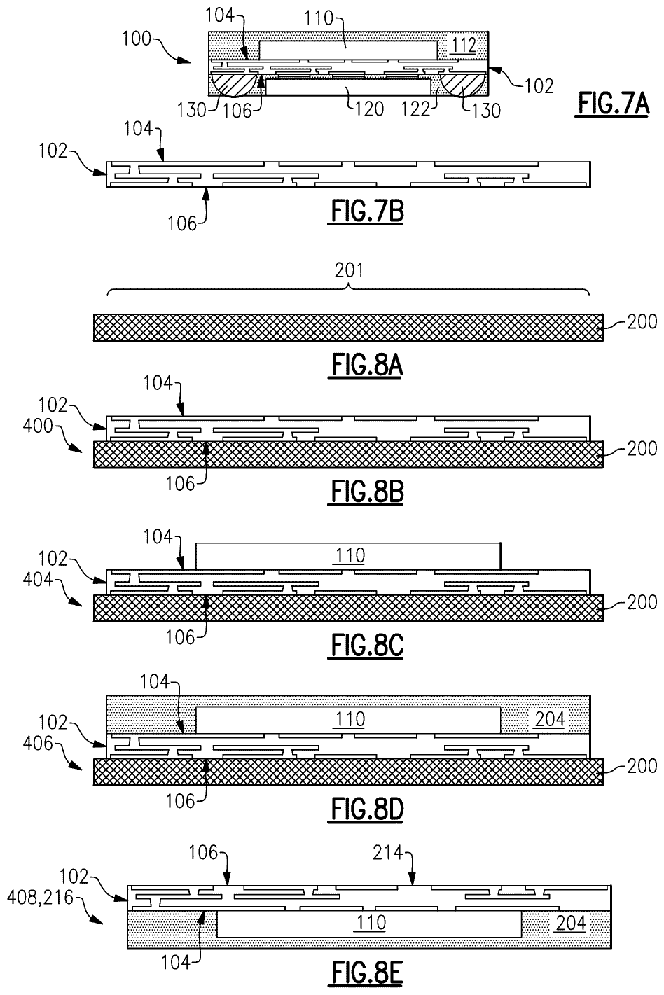

FIG. 7A show a dual-sided module 100 that is similar to the module 100 of FIG. 2J. In FIG. 7A, the dual-sided module 100 is shown to include an RDL 102 having examples of metal layers/traces, vias and pads for providing redistribution of electrical connections including those associated with the first and second components 110, 120. FIG. 7B shows an enlarged view of the RDL 102 by itself.

Referring to FIGS. 7A and 7B, a first side 104 of the RDL 102 is shown to be configured to have the first component 110 mounted thereto, and a second side 106 of the RDL 102 is shown to be configured to have the second component 120 mounted thereto. Thus, and depending on the first and second components 110, 120, first and second sides 104, 106 of the RDL 102 may or may not be the same.

It is noted that in the examples of FIGS. 2A to 2J, and more particularly to FIGS. 2C and 2E, the first side of a module being fabricated can be built first on a carrier (assembly 208 in FIG. 2C), and then an RDL can be provided or constructed on such a first-side portion after removal of the carrier to provide an assembly (216 in FIG. 2E) that acts as a platform for building the second side of the module being fabricated.

In some embodiments, a dual-sided module having one or more features as described herein can be fabricated by a process where an RDL is provided or constructed on a carrier before building of any side portion (e.g., first side portion) of the module. FIGS. 8A to 8E show various stages of such a process.

FIG. 8A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 8B shows a stage where a redistribution layer (RDL) 102 is formed or provided on carrier 200, so as to form an assembly 400. In some embodiments, the RDL 102 can include multiple layers, and such an RDL can be provided on the carrier 200 in a fully pre-fabricated RDL form, be built on the carrier 200 based on a partially pre-fabricated RDL form, or be built layer-by-layer on the carrier 200.

For example, suppose that an RDL includes a multi-layer assembly of a first polyimide layer, a first redistribution layer, a second polyimide layer, a second redistribution layer, a third polyimide layer and an array of under-bump metallization (UBM). In the context of such an example RDL, a fully pre-fabricated form having all of the foregoing parts can be provided on the carrier 200, a partially pre-fabricated form (e.g., a pre-fabricated assembly of first polyimide layer, first redistribution layer, second polyimide layer, second redistribution layer, and third polyimide layer) can be provided on the carrier 200 followed by formation of UBM array, or each of the foregoing parts can be built on the carrier 200 to form the assembly 400 of FIG. 8B.

In the example of FIG. 8B, it is noted that the RDL 102 includes a first side 104 and a second side 106. The second side 106 is shown to be attached to the carrier 200, and the first side 106 is shown to be exposed for building of a first-side portion of a dual-sided module being fabricated.

It will be understood that in some embodiments, the RDL 102 can be formed or provided so that an assembly similar to the assembly 400 of FIG. 8B has the first side 104 is attached to the carrier 200, and the second side 106 is exposed for building of a second-side portion of a dual-sided module being fabricated.

FIG. 8C shows a stage where a component 110 is mounted on the first side of the RDL 102 so as to form an assembly 404. In some embodiments, such a component (110) can be any one of components on the non-mounting side of dual-sided modules as described herein.

FIG. 8D shows a stage where a mold structure 204 is formed to partially or fully encapsulate the component 110 so as to form an assembly 406. In some embodiments, the mold structure 204 may or may not remain the same until the end of the fabrication process.

FIG. 8E shows a stage where the carrier 200 in the assembly 406 of FIG. 8D is removed to expose the second side 106 of the RDL 102, so as to form an assembly 408. In some embodiments, the assembly 408 can be similar to the assembly 216 of FIGS. 2E and 2F. Thus, in FIG. 8E, the assembly 408 is also indicated as 216, and the second side 106 also provides a surface 214 of the assembly 408/216. In some embodiments, subsequent module fabrication steps can be similar to the examples of FIGS. 2F to 2J.

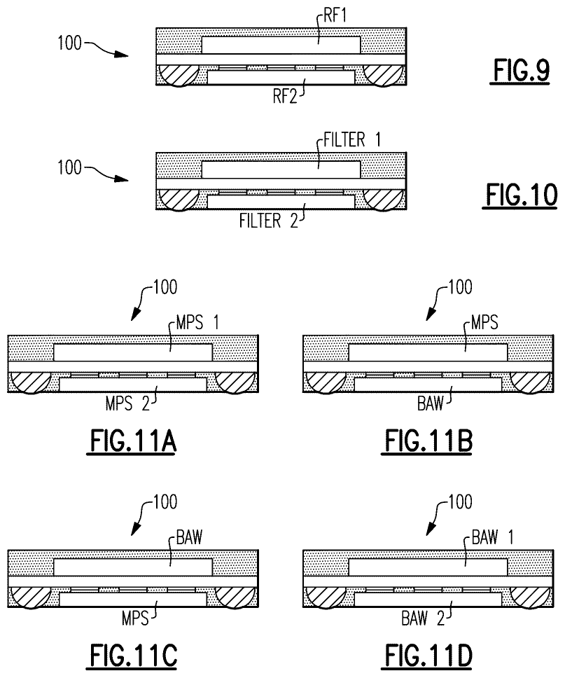

FIG. 9 shows that in some embodiments, a dual-sided module having one or more features as described herein can include a first component (110 in FIGS. 1A to 1E) implemented as a first radio-frequency (RF) device (RF1), and a second component (120 in FIGS. 1A to 1E) implemented as a second radio-frequency (RF) device (RF1). In some embodiments, each of the first and second RF devices can be implemented as a flip-chip device or be configured to provide flip-chip mounting functionality.

FIG. 10 shows that in some embodiments, the first RF device (RF1) of FIG. 9 can be a first filter device (Filter 1), and the second RF device (RF2) of FIG. 9 can be a second filter device (Filter 2).

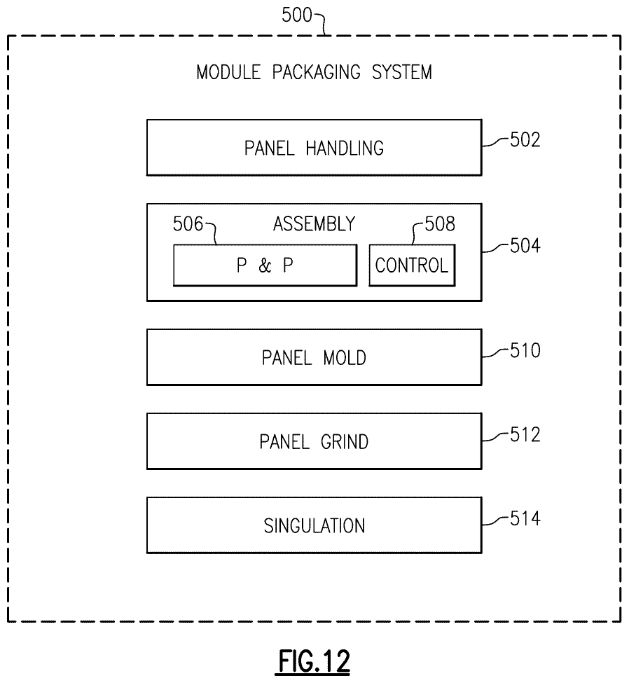

In some embodiments, each of the filter devices of FIG. 10 can be implemented as an acoustic filter. Such an acoustic filter can be, for example, a multilayer piezoelectric substrate (MPS) filter or a bulk acoustic wave (BAW) filter. In the context of such example acoustic filters, FIGS. 11A to 11D show non-limiting examples where first and second components (110, 120) of a dual-sided module can be implemented as different combinations of MPS and BAW filters.

For example, FIG. 11A shows that in some embodiments, a dual-sided module 100 having one or more features as described herein can have its first component implemented as a first MPS filter (MPS 1) and second component implemented as a second MPS filter (MPS 2).

In another example, FIG. 11B shows that in some embodiments, a dual-sided module 100 having one or more features as described herein can have its first component implemented as an MPS filter (MPS) and second component implemented as a BAW filter (BAW).

In yet another example, FIG. 11C shows that in some embodiments, a dual-sided module 100 having one or more features as described herein can have its first component implemented as a BAW filter (BAW) and second component implemented as an MPS filter (MPS).

In yet another example, FIG. 11D shows that in some embodiments, a dual-sided module 100 having one or more features as described herein can have its first component implemented as a first BAW filter (BAW 1) and second component implemented as a second BAW filter (BAW 2).

FIG. 12 shows that in some embodiments, one or more features of the present disclosure can be implemented in a module packaging system 500. Such a system can include a number of systems, subsystems, apparatus, etc. configured to provide respective functionalities. For example, a panel handling component 502 can be provided to allow handling of carriers, substrate panels and/or panel assemblies having mold layer(s) thereon.

In another example, an assembly component 504 can be provided to, for example, mounting of devices on either or both sides of substrate panels, and formation of conductive features on the second side of substrate panels. In some embodiments, such an assembly functionality can be supported by, for example, a pick-and-place apparatus 506 in operation with a controller 508.

In yet another example, a panel mold component 510 can be provided to form some or all of panel mold layers as described herein. In some embodiments, such panel mold layer forming component can be configured to form first and second mold layers corresponding to first and second sides of dual-sided modules.

In yet another example, a panel grind component 512 can be provided to perform thinning operations on either or both of the first and second mold layers. In some embodiments, the thinning operation described herein in reference to FIG. 2I can be achieved by the panel grind component 512. In some embodiments, the thinning operation described herein in reference to, for example, FIG. 4C can be achieved by the panel grind component 512.

In yet another example, a singulation component 514 can be provided to perform singulation operations on completed panel assemblies.

In some embodiments, some or all of the functional components of the module packaging system 500 of FIG. 12 can be performed under the control of, and/or facilitated by, a computer configured to execute one or more algorithms.

FIG. 13 shows a dual-sided module having one or more features as described herein, where a first component 110 is coupled to a first side of an RDL-substrate 102, and a second component 120 is coupled to a second side of the RDL-substrate 102. The coupling between first component 110 and the first side of the RDL-substrate 102 is shown to be provided by a first interconnect 191, and the coupling between second component 120 and the second side of the RDL-substrate 102 is shown to be provided by a second interconnect 192.

FIG. 13 shows that in some embodiments, the first interconnect 191 can be configured such that no gap is present between the first component 110 and the first side of the RDL-substrate 102. Such a configuration can be provided by patterning the mounting side of the first component 110 and the first side of the RDL-substrate 102 so that the first component 110 can be mated directly with the first side of the RDL-substrate 102 (e.g., in FIG. 2B and FIG. 8B), thereby providing a no-gap interconnect configuration therebetween.

FIG. 13 also shows that in some embodiments, the second interconnect 192 can be configured such that the second component 120 is mounted to the second side of the RDL-substrate 102 (e.g., in FIG. 2G1 and FIG. 2G2′) utilizing a surface mount technology (SMT) process. With such a mounting configuration, a gap is typically present between the second component 120 and the second side of the RDL-substrate 102. In some embodiments, such a gap can be filled with an underfill material. In some embodiments, such an underfill can be achieved during a molding process (e.g., in FIG. 2H), such that the underfill is formed from the same material as the second mold structure 122.

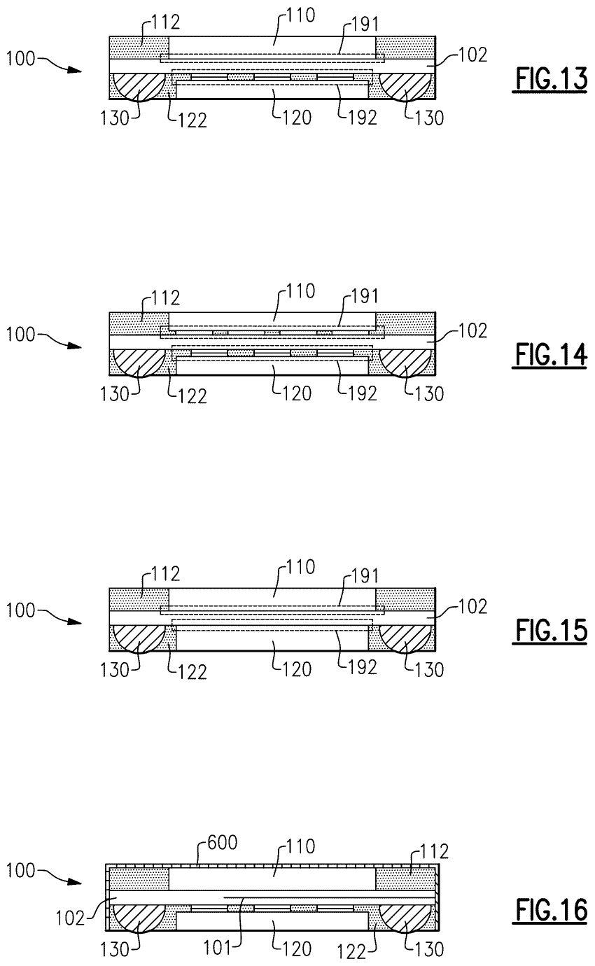

FIG. 14 shows that in some embodiments, a first interconnect 191 can be configured such that a first component 110 of a dual-sided module 100 is mounted to a first side of an RDL-substrate 102 utilizing a surface mount technology (SMT) process. With such a mounting configuration, a gap is typically present between the first component 110 and the first side of the RDL-substrate 102. In some embodiments, such a gap can be filled with an underfill material. In some embodiments, such an underfill can be achieved during a molding process, such that the underfill is formed from the same material as the first mold structure 112.

In the example of FIG. 14, a second interconnect 192 can be similar to the example of FIG. 13.

FIG. 15 shows that in some embodiments, a first interconnect 191 of a dual-sided module 100 can be similar to the example of FIG. 13, and a second interconnect 192 of the dual-sided module 100 can also be implemented to provide a no-gap interconnect configuration. In some embodiments, such a second interconnect (192) can be achieved by patterning the mounting side of the second component 120 and the second side of the RDL-substrate 102 so that the second component 120 can be mated directly with the second side of the RDL-substrate 102, thereby providing a no-gap interconnect configuration therebetween.

It will be understood that in some embodiments, a dual-sided module having one or more features as described herein can also be implemented such that a first interconnect (191) is similar to the example of FIG. 14 to provide a gap interconnect configuration, and a second interconnect (192) is similar to the example of FIG. 15 to provide a no-gap interconnect configuration.

In some embodiments, a dual-sided module having one or more features as described herein can include an electromagnetic (EM) shielding feature. For example, FIG. 16 shows a dual-sided module 100 fabricated as described herein. The dual-sided module 100 of FIG. 16 is shown to further include a conformal shielding layer 600, formed from electrically conductive material, that covers the non-mounting side (e.g., the upper side when viewed as shown) and side walls.

In the example of FIG. 16, the conformal shielding layer 600 can be electrically connected to an electrical ground plane 101. In some embodiments, such an electrical connection can be achieved through one or more of the side walls. In some embodiments, the ground plane 101 can be a part of the RDL 102 of the module 100.

In some embodiments, formation of the foregoing conformal shielding layer 600 can be achieved on singulated dual-sided modules, such as the singulated modules 100 of FIG. 5C.

FIG. 17 shows that in some embodiments, a dual-sided module 100 having one or more features as described herein can include a passive circuit element 610 implemented as a part of an RDL 102. In some embodiments, such a passive element can be implemented as one or more features printed on one or more of a plurality of layers of the RDL 102.

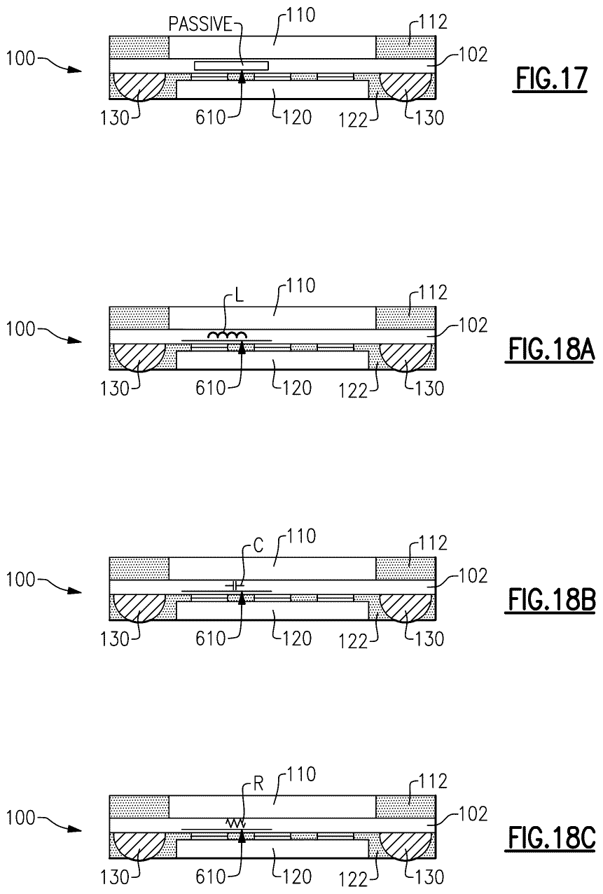

For example, FIG. 18A shows that in some embodiments, a dual-sided module 100 having one or more features as described herein can include an inductor 610 having inductance L implemented as a part of an RDL 102. In some embodiments, such an inductor can be implemented as a printed metal trace on one of a plurality of layers of the RDL 102.

In another example, FIG. 18B shows that in some embodiments, a dual-sided module 100 having one or more features as described herein can include a capacitor 610 having capacitance C implemented as a part of an RDL 102. In some embodiments, such a capacitor can be implemented as one or more printed metal features on one or more of a plurality of layers of the RDL 102.

In yet another example, FIG. 18C shows that in some embodiments, a dual-sided module 100 having one or more features as described herein can include a resistor 610 having resistance R implemented as a part of an RDL 102. In some embodiments, such a resistor can be implemented as one or more printed features on one or more of a plurality of layers of the RDL 102.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a redistribution layer having first and second sides;
a first-side portion implemented on the first side of the redistribution layer and including a first component mounted on the first side of the redistribution layer, the first-side portion further including a first mold structure implemented to at least partially encapsulate the first component; and
a second-side portion implemented on the second side of the redistribution layer and including a second component mounted on the second side of the redistribution layer, and a plurality of conductive mounting structures, the second-side portion further including a second mold structure implemented to at least partially encapsulate the second component, the second mold structure further encapsulating the conductive mounting features while providing respective exposed mounting surfaces of the conductive mounting features.

2. The packaged module of claim 1 wherein the redistribution layer is implemented as a multi-layer redistribution layer having a first outermost layer that defines the first side and a second outermost layer that defines the second side.

3. The packaged module of claim 2 wherein the first component is mounted directly on the first side, and the second component is mounted directly on the second side.

4. The packaged module of claim 1 wherein the first component is implemented as a die, and the second component is implemented as a die.

5. The packaged module of claim 4 wherein each of the first and second die is configured to provide a radio-frequency functionality.

6. The packaged module of claim 5 wherein the radio-frequency functionality of each of the first and second die includes a filtering functionality.

7. The packaged module of claim 6 wherein each of the first and second die is configured as an acoustic filter device.

8. The packaged module of claim 7 wherein the first acoustic filter device is a multilayer piezoelectric substrate (MPS) filter or a bulk acoustic wave (BAW) filter, and the second acoustic filter device is an MPS filter or a BAW filter.

9. The packaged module of claim 1 wherein the conductive mounting structures of the second-side portion are implemented as ball-shaped structures or as metal posts.

10. The packaged module of claim 1 wherein first mold structure is implemented fully encapsulate non-mounting surface and side walls of the first component.

11. The packaged module of claim 1 wherein the first mold structure is implemented to expose a non-mounting surface of the first component.

12. The packaged module of claim 11 wherein the exposed non-mounting surface of the first component results from a thinning operation that removes a portion of the first component.

13. (canceled)

14. The packaged module of claim 1 wherein the second mold structure is implemented fully encapsulate non-mounting surface and side walls of the second component.

15. The packaged module of claim 1 wherein the second mold structure is implemented to expose a non-mounting surface of the second component.

16. (canceled)

17. (canceled)

18. The packaged module of claim 1 further comprising an electromagnetic shielding feature including a conductive shielding layer that substantially covers all sides of the packaged module except a mounting side associated with the exposed mounting surfaces of the conductive mounting features, the conductive shielding layer electrically connected to a ground plane within the redistribution layer.

19. (canceled)

20. The packaged module of claim 1 wherein the first component is mounted on the first side of the redistribution layer to provide a no-gap configuration therebetween.

21. (canceled)

22. (canceled)

23. (canceled)

24. (canceled)

25. The packaged module of claim 1 wherein the redistribution layer includes a passive circuit element implemented as one or more features printed on one or more layers of the redistribution layer.

26. The packaged module of claim 25 wherein the passive circuit element includes an inductor, a capacitor or a resistor.

27. A method for manufacturing a packaged module, the method comprising:
providing a carrier;
forming a first-side portion of a dual-sided module on the carrier;
removing the carrier from the first-side portion to provide a surface;
providing or forming a redistribution layer on the first-side portion, such that a first side of the redistribution layer engages the surface of the first-side portion and a second side of the redistribution layer is opposite from the first side; and
forming a second-side portion of the dual-sided module on the second side of the redistribution layer.

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. A method for manufacturing packaged modules, the method comprising:
providing a carrier;
providing or forming a redistribution layer on the carrier, such that the redistribution layer includes first and second sides with the second side engaging the carrier;
forming a first-side portion of a dual-sided module on the first side of the redistribution layer;
removing the carrier from the second side of the redistribution layer; and
forming a second-side portion of the dual-sided module on the second side of the redistribution layer.

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)
